(19) United States
(12) Patent Application Publication
(10) Pub. No.: US 2005/0218443 A1
(43) Pub. Date: Oct. 6, 2005

(54) Ferroelectric memory element and its manufacturing method

(76) Inventors: Hiroaki Tamura, Kuwanashi (JP); Teruo Tagawa, Suwa shi (JP)

Correspondence Address: HARNESS, DICKEY & PIERCE, P.L.C., P.O. BOX 828, BLOOMFIELD HILLS, MI, 48303, US

(21) Appl. No.: 11/089,432

(22) Filed: Mar. 24, 2005

(30) Foreign Application Priority Data
Mar. 26, 2004 (JP) 2004092013

(51) Int. Cl. H01L 29/76

(52) U.S. Cl. 257/310

(57) ABSTRACT

A ferroelectric capacitor is covered with a hydrogen barrier film, and an inner wall of a contact hole provided above an upper electrode of the ferroelectric capacitor is also covered with a hydrogen barrier film, thereby preventing hydrogen from infiltrating in the ferroelectric capacitor through a contact hole.

### RELATED APPLICATIONS

This application claims priority to Japanese Patent Application No. 2004-092013 filed Mar. 26, 2004 which is hereby expressly incorporated by reference herein in its entirety.

### BACKGROUND

1. Technical Field

The present invention relates to a method for manufacturing ferroelectric memory elements.

2. Related Art

Nonvolatile memory elements (ferroelectric memory elements) using a spontaneous polarization characteristic to ferroelectric are attracting attention as ultimate memories with the possibility of replacing most memories including not only currently existing nonvolatile memories but also SRAMs (static random access memories) and DRAMs, because of their high-speed writing/reading and low-voltage operation characteristics. Though many candidates have been enumerated as ferroelectric raw material, perovskite type oxides including lead zirconate titanate (PZT) and bismuth layered compounds such as SrBi₂Ta₂O₉ are viewed particularly hopeful because they show extremely excellent ferroelectric characteristics.

In general, when the above-described oxide material is used as a capacitor insulation layer, an interlayer insulation film such as SiO₂ is covered mainly for the purpose of electrically insulating memory elements one from the other, after an upper electrode is formed. As a method for forming such a film, a CVD (Chemical Vapor Deposition) method that excels in the step-difference coating property is generally used. However, if such a film forming method is used, hydrogen is generated as a reactive by-product. Especially, when activated hydrogen penetrates SiO₂ and the upper electrode and reaches the ferroelectric thin film, its reducing action ruins the crystallinity of the ferroelectric, and electrical characteristics of the ferroelectric are considerably deteriorated. Moreover, when a MOS transistor is used as a switching element, its characteristics are deteriorated by lattice defects in the silicon single crystal generated in the device manufacturing process. Therefore, a heat-treatment needs to be conducted in a hydrogen-mixed nitrogen gas in the final state. However, the hydrogen concentration in this stage is much higher than the concentration at the time of forming the interlayer insulation film described above, the damage inflicted on the ferroelectric thin film becomes more serious.

To prevent the reducing deterioration of the ferroelectric capacitor caused by hydrogen, a method is attempted to cover a ferroelectric thin film capacitor after it is formed with a protection film to prevent infiltration of hydrogen. This protection film is generally called a hydrogen barrier film. The ferroelectric capacitor is isolated from the hydrogen atmosphere when the interlayer insulation film is formed because of the presence of the protection film, such that deterioration of the electrical characteristics from the initial values can be prevented.

However, it is necessary to form a contact hole over the upper electrode of the ferroelectric capacitor in order to electrically connect the upper electrode to a wiring. In other words, the hydrogen barrier film is also removed at the contact section, which causes a problem in that the capacitor cannot be protected from a hydrogen atmosphere that is generated after the wiring layer is formed. A method to provide an upper electrode itself with a hydrogen barrier function is often enumerated as one measure to solve the problem. Oxide materials that are electroconductive are being researched aggressively, and IrOx can be a representative example among them. However, depending on the kind of the ferroelectric material, the capacitor's initial characteristics may not be secured if an iridium oxide film is used as an upper electrode. When platinum is used, the initial characteristics can be secured, but the crystallinity of the ferroelectric is considerably damaged because platinum exhibits a catalytic action to hydrogen. Although the damage of the capacitor caused when the wiring layer is formed can be recovered by a recovery treatment such as heating in an oxygen atmosphere or the like, reducing damages may occur again if hydrogen is generated in a later step because the contact hole is open.

It is an object of present invention to provide a ferroelectric memory element with a device structure that can suppress reducing damages to a ferroelectric layer even when an upper electrode comprises a material that does not exhibit a hydrogen barrier function. Also, it is an object of present invention to provide a ferroelectric memory element that can prevent process-originated reducing deterioration of a ferroelectric thin film even when a material having a hydrogen barrier function is not used as an upper electrode.

### SUMMARY

A ferroelectric memory element in accordance with the present invention include: a ferroelectric capacitor composed of a lower electrode, an oxide ferroelectric thin film and an upper electrode which are formed on a semiconductor substrate; an interlayer insulation film formed on the ferroelectric capacitor; a contact hole opened in the interlayer insulation film above the upper electrode; and a wiring layer connected to the upper electrode through the contact hole, and the ferroelectric memory element is characterized in that a thin film having a hydrogen barrier function is disposed on an inner wall of the contact hole.

The structure described above provides an effect in that, among hydrogen generated at the time of forming the wiring layer, hydrogen that may infiltrate in the contact hole through the above-described interlayer insulation film can be intercepted.

The ferroelectric memory element in accordance with the present invention is characterized in that a thin film having a hydrogen barrier function is formed on the interlayer dielectric film.

The structure described above provides an effect to prevent infiltration of hydrogen through the surface of the interlayer insulation film.

The ferroelectric memory element in accordance with the present invention is characterized in that a surface of the wiring layer is covered with a thin film having a hydrogen barrier function.

The structure described above provides an effect to prevent hydrogen generated at the time of forming the wiring layer from infiltrating through the upper surface of the wiring layer into the contact hole.

The ferroelectric memory element in accordance with the present invention is characterized in that a side surface of the wiring layer is covered with a thin film having a hydrogen barrier function.

The structure described above provides an effect in that hydrogen generated in steps after the wiring layer formation can be prevented from infiltrating through the side surface of the wiring layer into the contact hole.

A ferroelectric memory element in accordance with the present invention is characterized in that the wiring layer comprises a precious metal.

The structure described above provides an effect in that the characteristics can be recovered by heating the ferroelectric capacitor at high temperatures after the wiring layer is formed.

The ferroelectric memory element in accordance with the present invention is characterized in that an oxide of iridium is disposed at a lower most layer of the wiring layer.

The structure described above provides an effect in that hydrogen that infiltrates in the wiring layer after the wiring layer has been formed is prevented from reaching through the contact hole to the upper electrode of the ferroelectric capacitor.

The ferroelectric memory element in accordance with the present invention is characterized in that a side surface of the ferroelectric capacitor is covered with a thin film having a hydrogen barrier function.

The structure described above provides an effect in that the ferroelectric capacitor can be protected from hydrogen that is generated when the interlayer insulation film is formed.

The ferroelectric memory element in accordance with the present invention is characterized in that a thin film having a hydrogen barrier function is disposed below the ferroelectric capacitor.

The structure described above provides an effect in that hydrogen generated after the ferroelectric capacitor is formed can be prevented from reaching the ferroelectric through the lower section of the ferroelectric capacitor.

The ferroelectric memory element in accordance with the present invention is characterized in that the thin film having a hydrogen barrier function is an oxide including one or more elements selected from aluminum, titanium, hafnium, zirconium, magnesium and tantalum.

The structure described above provides an effect in that a more excellent hydrogen barrier function can be obtained.

The ferroelectric memory element in accordance with the present invention is characterized in that a region of the interlayer insulation film which contacts the ferroelectric capacitor is an O₃-TEOS SiO₂ film.

The structure described above provides an effect in that hydrogen damages at the time of forming the interlayer insulation film can be reduced.

A method for manufacturing a ferroelectric memory element in accordance with the present invention is characterized in comprising the steps of: a) stacking a lower electrode, an oxide ferroelectric thin film and an upper electrode in layers on a semiconductor substrate, and then patterning the layers to form a ferroelectric capacitor; b) depositing an interlayer insulation film on the ferroelectric capacitor; c) opening a contact hole in the interlayer insulation film above the upper electrode; and d) coating a thin film having a hydrogen barrier function on the interlayer insulation film and within the contact hole; e) etching back the thin film having a hydrogen barrier function to remove the thin film having a hydrogen barrier function covering a bottom section of the contact hole; f) depositing a conductive material in the contact hole to form a wiring layer that connects to the upper electrode.

According to the method described above, among hydrogen generated at the time of forming the wiring layer, hydrogen that may infiltrate in the contact hole through the above-described interlayer insulation film can be intercepted.

The method for manufacturing a ferroelectric memory element in accordance with the present invention is characterized in that, before the step e), an area other than an opening section of the contact hole is covered with a resist beforehand.

The method described above provides an effect in that hydrogen generated in a later process can be prevented from infiltrating through the surface of the interlayer insulation film, because the thin film having a hydrogen barrier function remains on the interlayer insulation film.

The method for manufacturing a ferroelectric memory element in accordance with the present invention is characterized in that, in the step d), the thin film having a hydrogen barrier function is deposited by an Atomic-Layer CVD method (atomic layer deposition method).

The method described above provides an effect in that the thin film having a hydrogen barrier function can also cover the inner wall of the contact hole with good coverage.

The method for manufacturing a ferroelectric memory element in accordance with the present invention is characterized in that the Atomic-Layer CVD method (atomic layer deposition method) uses ozone as an oxidant to organic raw materials.

The method described above provides an effect in that the film quality of the thin film having a hydrogen barrier function can be improved, and the Atomic-Layer CVD process does not adversely affect the characteristics of the ferroelectric capacitor.

The method for manufacturing a ferroelectric memory element in accordance with the present invention is characterized in that, after the step c), the semiconductor substrate is heated in an oxygen atmosphere.

The method described above provides an effect in that the characteristics of the ferroelectric capacitor damaged at the time of opening the contact hole can be recovered.

The method for manufacturing a ferroelectric memory element in accordance with the present invention is characterized in that the heating is conducted below a crystallization temperature of the oxide ferroelectric thin film.

The method described above provides an effect in that the characteristics of the ferroelectric capacitor can be recovered without giving damages to elements on the semiconductor substrate.

The method for manufacturing a ferroelectric memory element in accordance with the present invention is characterized in that, in the step f), a thin film having a hydrogen barrier function is formed continuously on the conductive material.

The method described above provides an effect in that hydrogen generated at the time of patterning the wiring layer can be prevented from infiltrating through the upper surface of the wiring layer into the contact hole because the thin film having a hydrogen barrier function is formed on the upper surface of the wiring layer.

### BRIEF DESCRIPTION OF THE DRAWINGS

FIG. 1 is a view schematically showing a step of forming a device in accordance with Embodiment Example 1.

FIG. 2 is a view schematically showing a step of forming a device in accordance with Embodiment Example 1.

FIG. 3 is a view schematically showing a step of forming a device in accordance with Embodiment Example 1.

FIG. 4 is a view schematically showing a step of forming a device in accordance with Embodiment Example 1.

FIG. 5 is a view schematically showing a step of forming a device in accordance with Embodiment Example 1.

FIG. 6 is a view schematically showing a step of forming a device in accordance with Embodiment Example 1.

FIG. 7 is a view schematically showing a step of forming a device in accordance with Embodiment Example 1.

FIG. 8 is a view schematically showing a step of forming a device in accordance with Embodiment Example 1.

FIG. 9 is a view schematically showing a step of forming a device in accordance with Embodiment Example 1.

FIG. 10 is a view schematically showing a step of forming a device in accordance with Embodiment Example 1.

FIG. 11 is a hysteresis curve in an initial state obtained with Sample 1 in accordance with Embodiment Example 1.

FIG. 12 is a hysteresis curve obtained after wiring with Sample 1 in accordance with Embodiment Example 1.

FIG. 13 is a hysteresis curve obtained after wiring with Sample 2 in accordance with Embodiment Example 1.

FIG. 14 is a view schematically showing a step of forming a device in accordance with Embodiment Example 2.

FIG. 15 is a view schematically showing a step of forming a device in accordance with Embodiment Example 2.

FIG. 16 is a view schematically showing a step of forming a device in accordance with Embodiment Example 2.

FIG. 17 is a view schematically showing a step of forming a device in accordance with Embodiment Example 2.

FIG. 18 is a hysteresis curve obtained with Sample 3 in accordance with Embodiment Example 2.

FIG. 19 is a hysteresis curve obtained with Sample 1 in accordance with Embodiment Example 1.

FIG. 20 is a view schematically showing a step of forming a device in accordance with Embodiment Example 3.

FIG. 21 is a view schematically showing a step of forming a device in accordance with Embodiment Example 3.

FIG. 22 is a view schematically showing a step of forming a device in accordance with Embodiment Example 3.

FIG. 23 is a view schematically showing a step of forming a device in accordance with Embodiment Example 3.

FIG. 24 is a view schematically showing a step of forming a device in accordance with Embodiment Example 3.

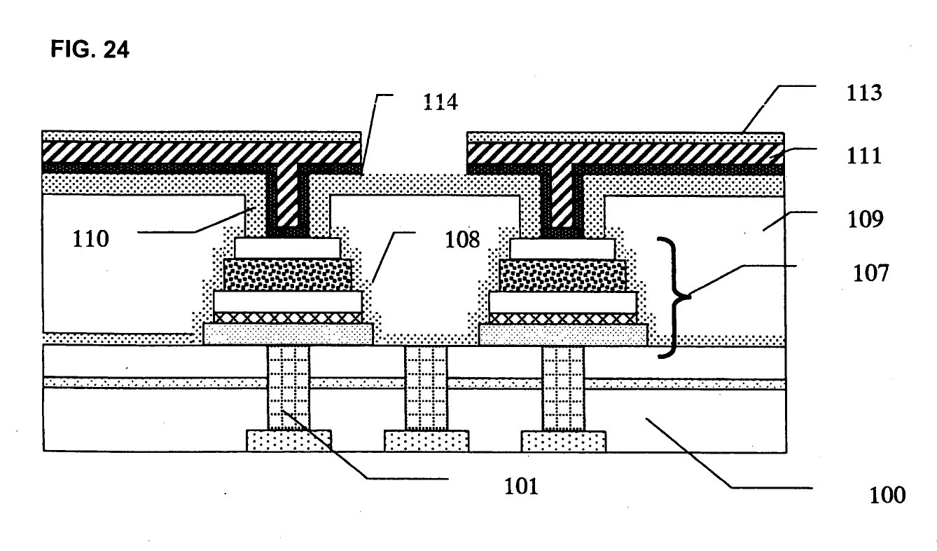

FIG. 25 is a view schematically showing a step of forming a device in accordance with Embodiment Example 4.

FIG. 26 is a hysteresis curve obtained with Sample 3 in accordance with Embodiment Example 4.

FIG. 27 is a hysteresis curve obtained with Sample 4 in accordance with Embodiment Example 4.

FIG. 28 is a hysteresis curve obtained with a sample manufactured in accordance with Embodiment Example 4.

### DETAILED DESCRIPTION

Embodiments of the present invention are described below with reference to the accompanying drawings.

### EMBODIMENT EXAMPLE 1

First, a process of stacking layers of a ferroelectric thin film is schematically described.

A resist pattern for forming contact holes was formed by a lithography process on a semiconductor substrate 100 having switching transistors formed thereon, and then contact holes were opened by a dry etching method. After a tungsten film was deposited by a chemical vapor deposition (CVD) method, the tungsten film was polished by chemical and mechanical polishing, thereby forming tungsten plugs 101 in the contact holes.

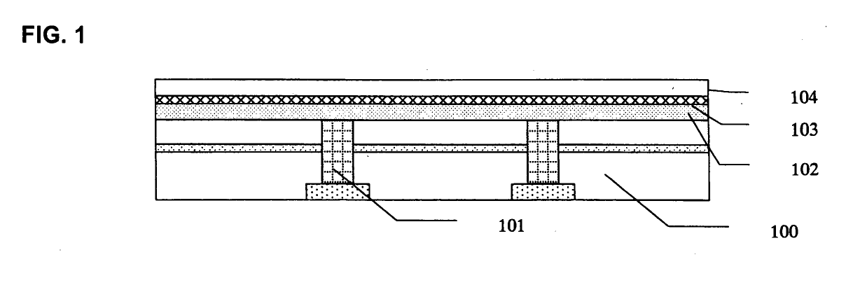

Next, a titanium nitride film was formed by a sputter method as a barrier metal layer 102 between a lower electrode and the tungsten plugs 101. Then, an iridium oxide film 103 and platinum 104 were laminated thereon as a lower electrode. A laminated structure obtained by the above-described process is shown in FIG. 1.

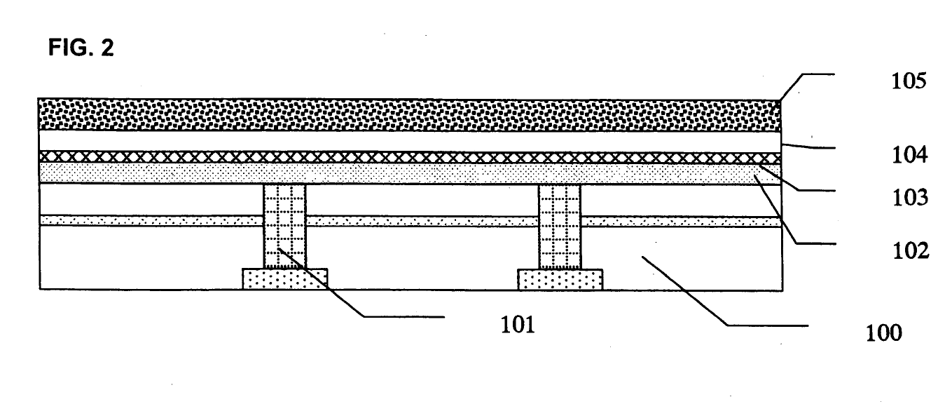

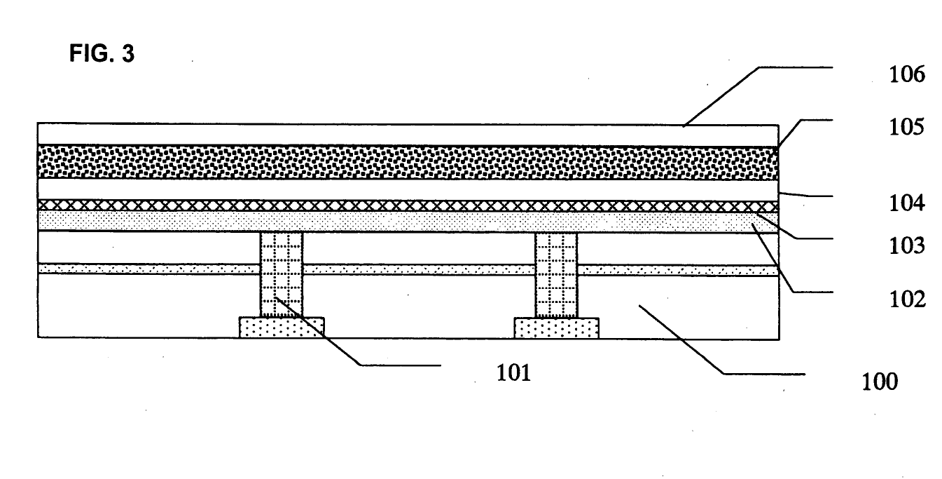

An organic solution including lead, titanium and zirconium was coated on the platinum 104 by a spin coat method, which was then dried to obtain a precursor film. The process of spin coating and drying is repeated until the precursor film reached a desired film thickness. By conducting an oxygen anneal treatment for five minutes at 525° C. at the end, Pb(Zr, Ti)O₃ (hereafter referred to as PZT) 105 that was a crystalline thin film was obtained (FIG. 2). A film of platinum 106 was formed thereon as an upper electrode by a sputter method (FIG. 3).

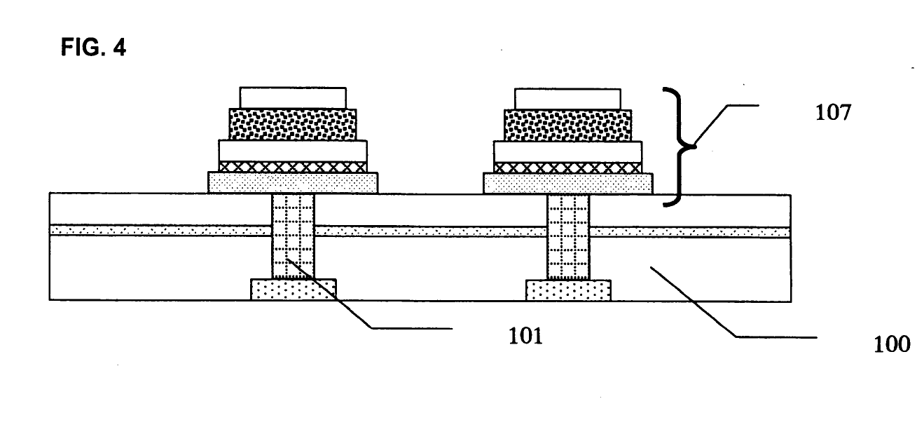

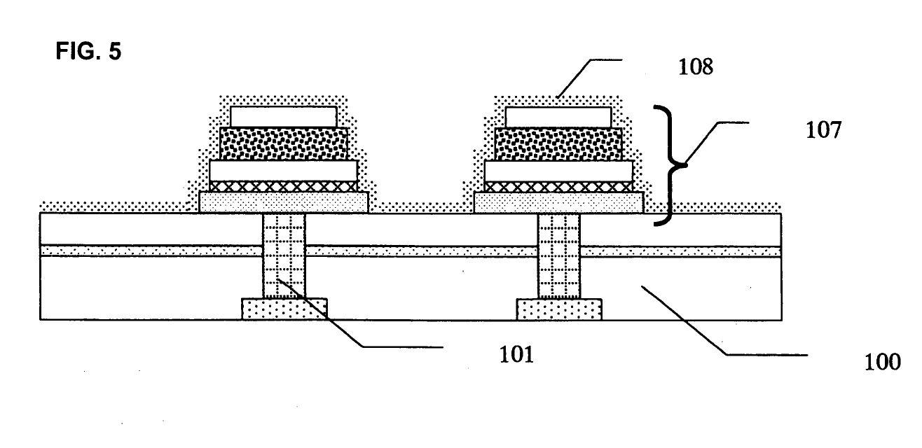

Next, the lower electrode, the PZT thin film, and the upper electrode were patterned to a desire size, whereby a PZT thin film capacitor 107 was formed (FIG. 4). An anneal treatment at 675° C. was conducted again for 5 minutes in an oxygen atmosphere, and an AlOₓ thin film 108 was formed as a hydrogen barrier film to cover the surface of the capacitor. As the film forming method, a sputter method, a CVD method, an atom layer deposition method, an atomic layer CVD (ACLVD) method can be enumerated (FIG. 5).

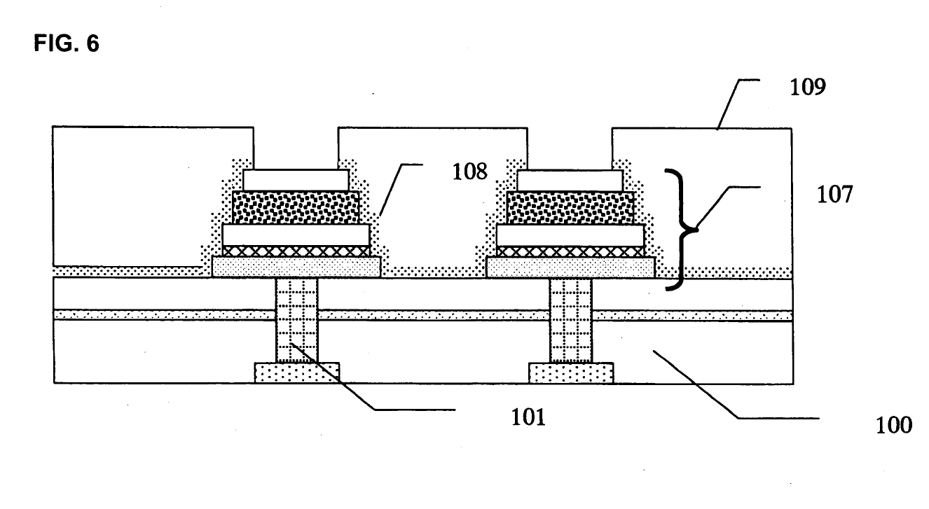

By using a plasma chemical vapor deposition method, a TEOS (tetraethylorthosilicate)—SiO₂ film 109 was deposited on the AlOx thin film 108. Opening sections were formed to obtain electrical contacts with the upper electrodes of the ferroelectric thin film capacitors (FIG. 6). Next, the substrate was heated. This was aimed at discharging moisture contained in the interlayer insulation film. If the interlayer insulation film is an ozone TEOS-SiO₂ film, the substrate may preferably be heated under conditions of annealing conducted after the PZT thin film capacitor is formed. In this embodiment example, a heat-treatment in an oxygen atmosphere was conducted for five minutes at 675° C. If the interlayer insulation film is a plasma TEOS-SiO₂ film, the treatment temperature may be lower than this temperature because the moisture content of this film is lower than that of an ozone TEOS-SiO₂ film. This heating is aimed not at discharging moisture but rather at recovering plasma damages inflicted on the PZT thin film capacitor.

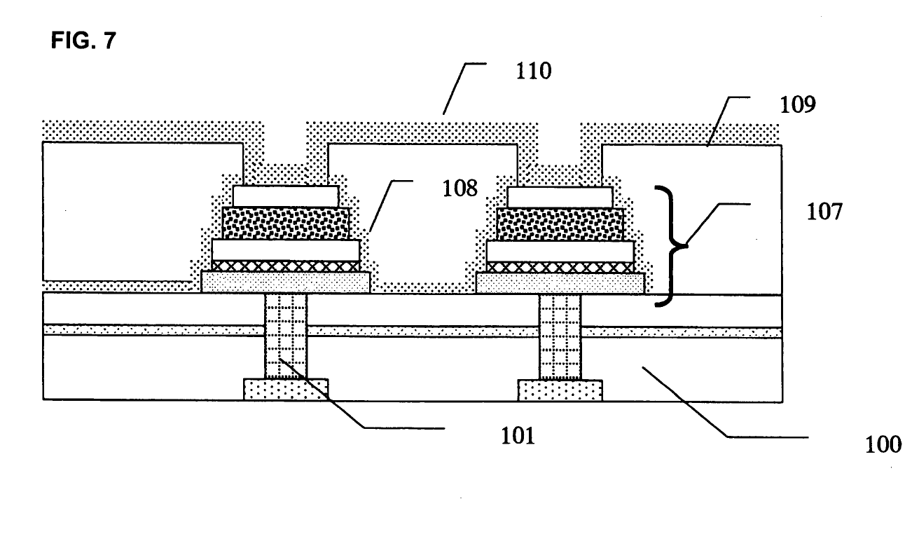

An AlOₓ thin film 110 was deposited again in the openings (contact holes) and on the above-described TEOS-SiO₂ film (FIG. 7). It is preferable to use an ALCVD method as the film forming method. Because the contact hole is formed by dry etching, its inner wall is almost vertical, and therefore it is extremely difficult to form an AlOx thin film to this wall surface. In this respect, the ALCVD method promises excellent step coverage, such that an AlOx thin film can be formed on the inner walls of the contact holes with the same film thickness as that on the TEOS-SIO₂ film.

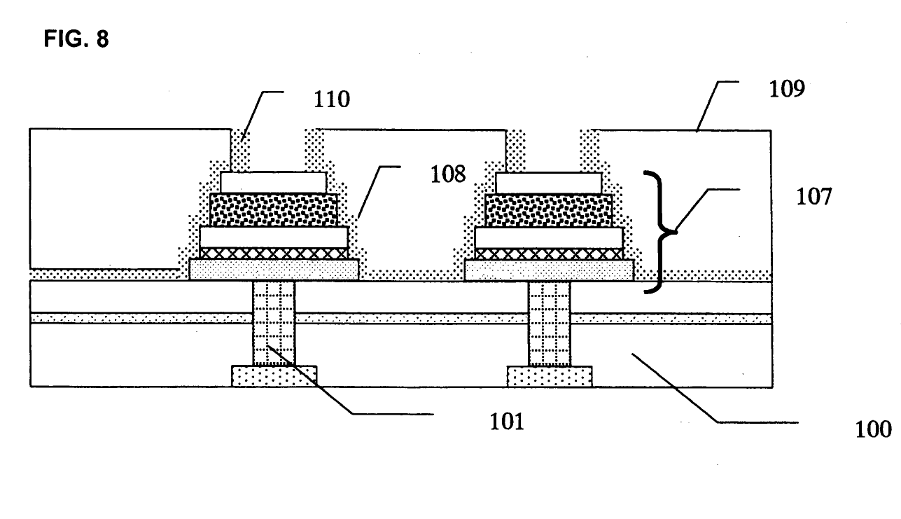

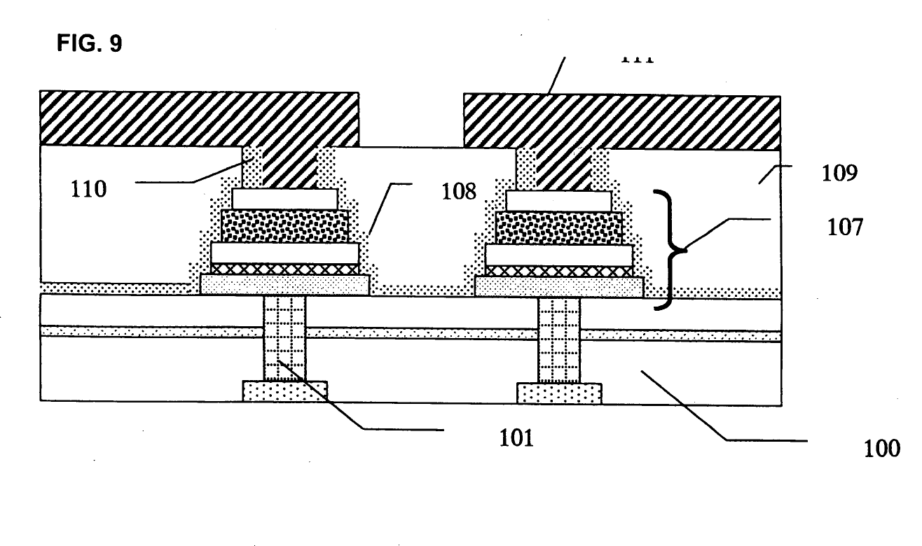

Next, coating of a resist was omitted, and a front side etching was conducted. In other words, the AlOx thin film was etched in this step. However, the amount of etching becomes not uniform in the surface but selective. More specifically, while etching of the AlOₓ film covering the inner wall of the contact hole does not advance, the AlOₓ thin films on the TEOS-SiO₂ and at the bottom of the contact hole are removed. By stopping the etching at the stage when the AlOₓ thin films on the TEOS-SiO₂ and at the bottom of the contact hole were removed, the AlOₓ thin film was left only on the inner wall of the contact hole, as shown in FIG. 8. By forming a wiring 111 with platinum, an electrical contact can be obtained with the upper electrode of the PZT thin film capacitor 107. The obtained device structure is shown in FIG. 9. This structure is particularly called a stacked type, and is one of the extremely advantageous memory cell structures for higher integration of the memory cells (Sample 1).

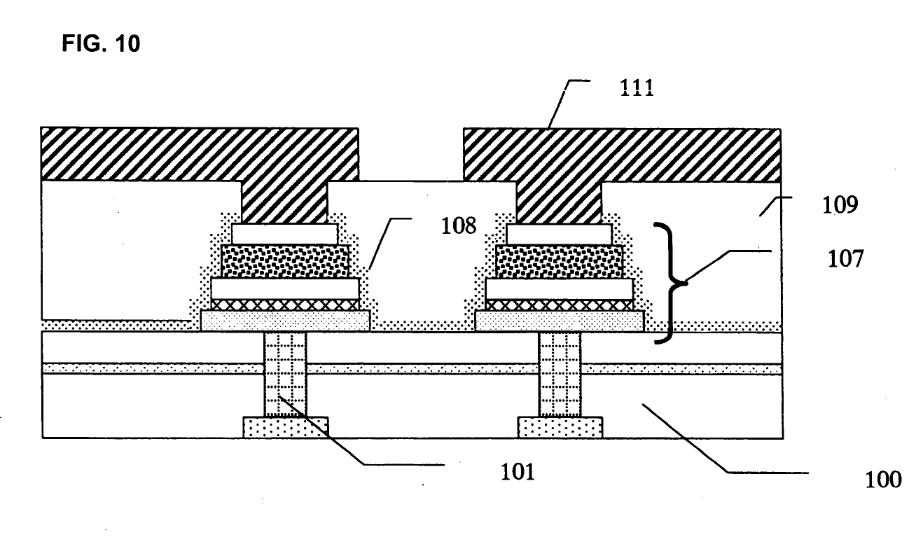

On the other hand, a sample was manufactured by a conventional method for comparison. Specifically, an AlOx thin film 110 in the contact hole was omitted. FIG. 10 schematically shows a configuration of the device. Compared to FIG. 9, the difference resides only in the presence or absence of the AlOₓ thin film in the contact hole inner wall, and other processes are common (Sample 2).

The characteristics of the memory devices that were obtained by the respective manufacturing methods were compared. Attention was paid to ferroelectric characteristics of the ferroelectric thin film capacitors. When a suitable AC voltage is impressed across the upper and lower electrodes, a charge of a predetermined amount that depends on the magnitude and direction of the applied voltage is generated between the upper and lower electrodes. When the applied voltage is plotted along the axis of abscissas and the amount of charge is plotted along the axis of ordinate to monitor this phenomenon, a hysteresis loop peculiar to the ferroelectric which originates in the inversion of the polarization axis is obtained. The amount of polarization at zero voltage is called the amount of remanence, and the larger this value, the larger the amount of charge, in other words, the larger the signal, which is advantageous in reading operations.

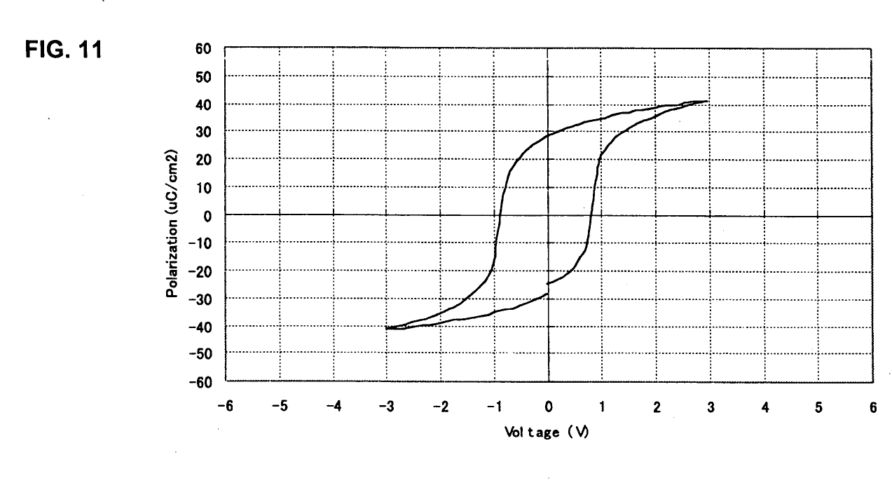

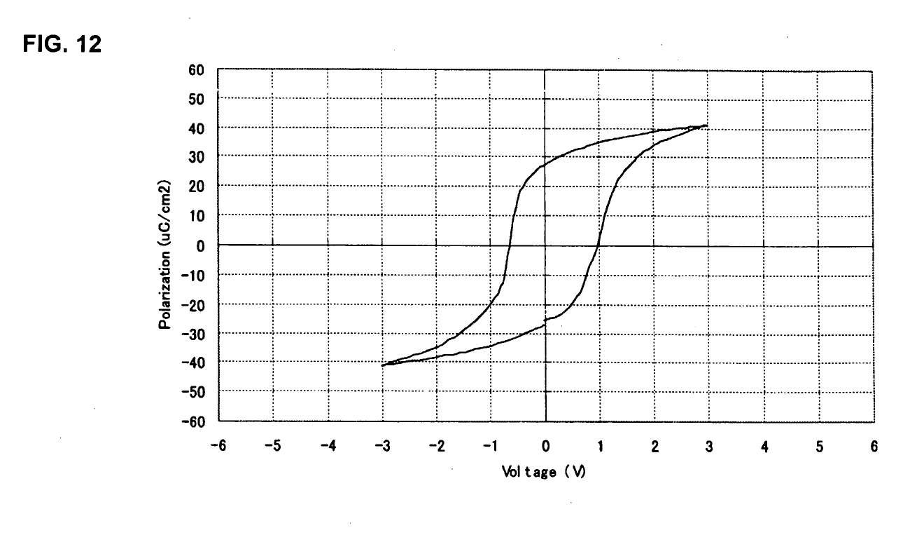

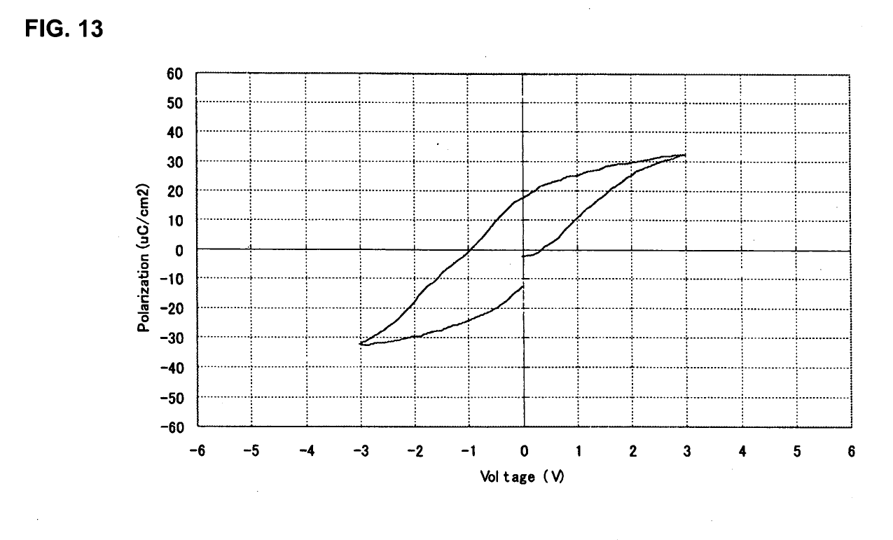

FIG. 11 shows a hysteresis loop obtained immediately after the PZT capacitor was formed. FIG. 12 and FIG. 13 show hysteresis loops obtained with Sample 1 and Sample 2, respectively. It is clear from the figures that Sample 1 has a less deterioration in the ferroelectric characteristics compared to the PZT capacitor immediately after formation. On the other hand, in Sample 2, the hysteresis loop became thinner, and it is therefore understood that drastic characteristic deterioration occurred. It became clear that a large characteristic difference appeared after the process due to the difference in the manufacturing process of the two samples. In other words, it is assumed that, depending on the presence or absence of the AlOₓ thin film 110 on the inner wall of the contact hole, the degree of process deterioration became greater.

In the method for manufacturing the ferroelectric memory described as the embodiment example, hydrogen generated in the step of forming the wiring 111 is a significant factor that causes the characteristic deterioration of the capacitor. The generated hydrogen diffuses in the TEOS-SiO₂ thin film 109 from its surface, and a certain amount reaches around the contact hole. However, in Sample 1, because the sidewall of the PZT thin film capacitor 107 as well as the inner wall of the contact hole is covered with the AlOₓ thin film, hydrogen cannot infiltrate in the contact hole. For this reason, the characteristic deterioration of the PZT hardly occurs because hydrogen would not reach the PZT thin film capacitor even after formation of the wiring 111. On the other hand, in Sample 2, because an AlOₓ thin film is not provided on the inner wall of the contact hole, hydrogen infiltrates here, and reaches the upper electrode of the PZT thin film capacitor. It is assumed that the hydrogen is activated here by the catalysis action of the upper electrode, and reaches the PZT thin film, and the ferroelectric characteristic of the PZT is considerably damaged.

To prevent hydrogen generated in the step of forming the wiring 111 from reaching the PZT thin film, it was found that it should be extremely important to arrange the AlOₓ thin film 110 in the contact hole as a hydrogen barrier film.

### EMBODIMENT EXAMPLE 2

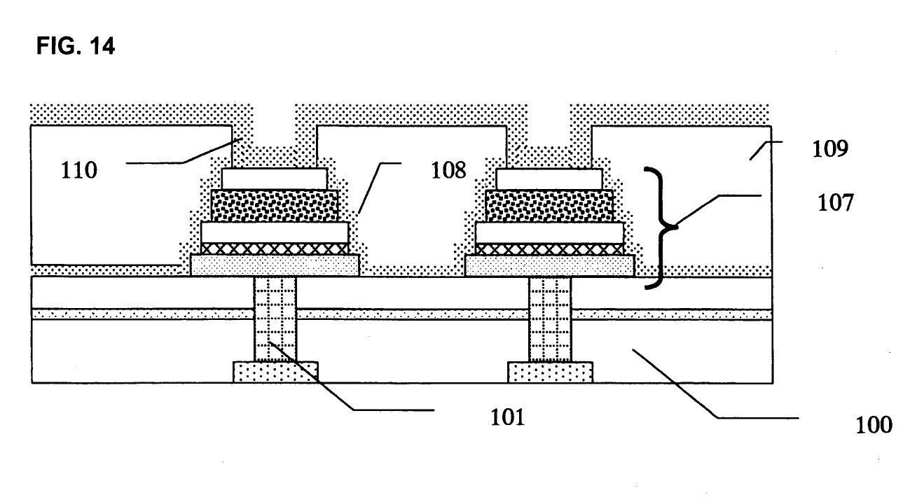

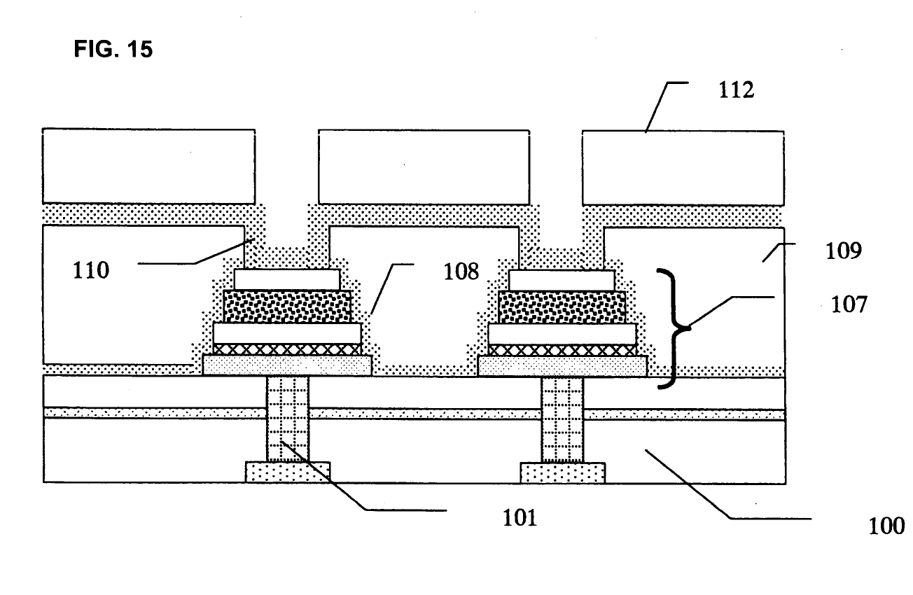

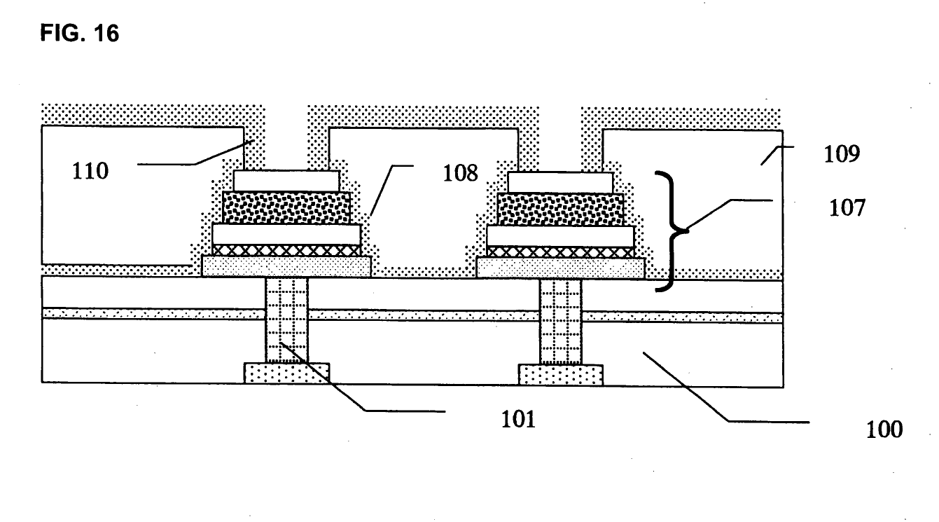

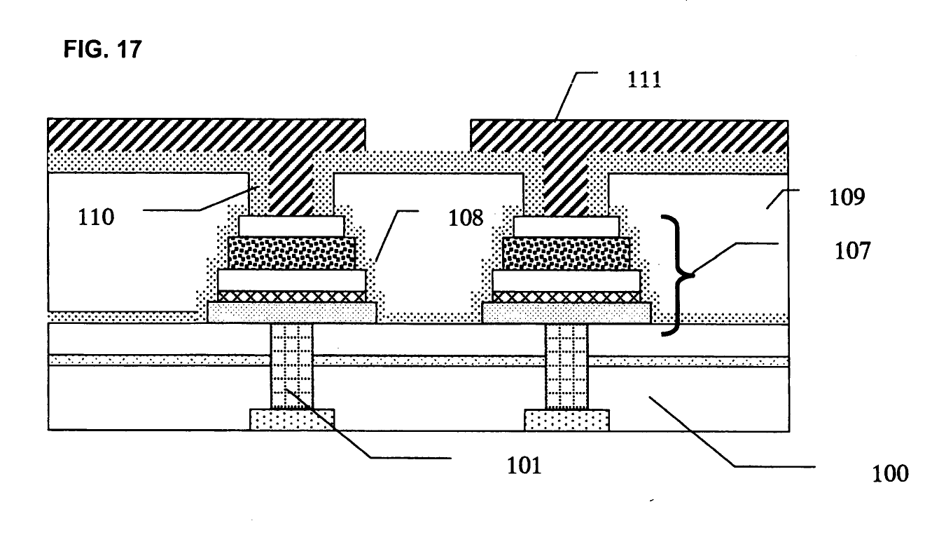

A structure up to an AlOₓ thin film 110 was formed by the method similar to Embodiment Example 1 (FIG. 14). Next, a resist is coated on the AlOₓ thin film 110 and exposed to light, thereby opening only contact holes (FIG. 15). In this state, the AlOₓ thin film 110 at the bottom of the contact holes was removed by dry etching. The device structure obtained after the resist was removed is shown in FIG. 16. A wiring 111 was formed with platinum (FIG. 17). This is referred to as Sample 3. Compared to Sample 1 (FIG. 9) in Embodiment Example 1, the difference resides in that the AlOₓ thin film 110 is disposed under the wiring 111. Differences which the difference in the device structure gave to the characteristics of the PZT thin film capacitor 107 were examined.

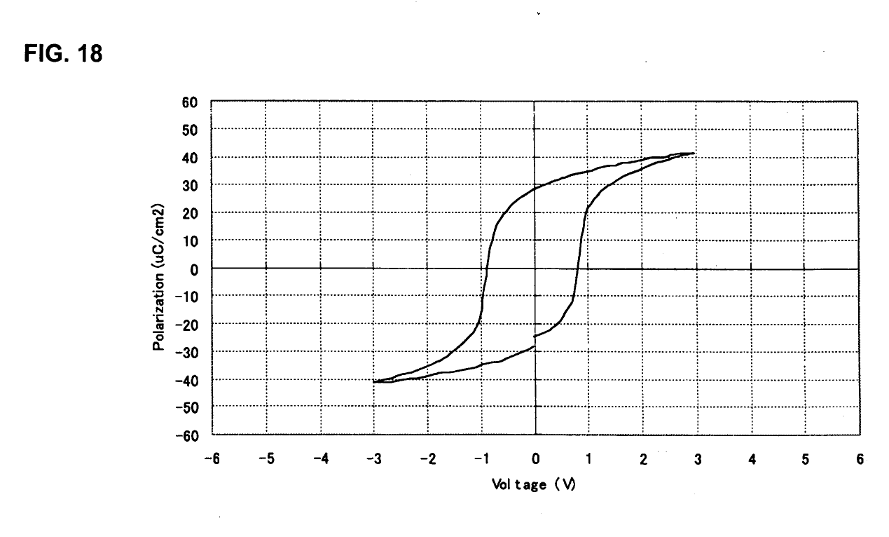

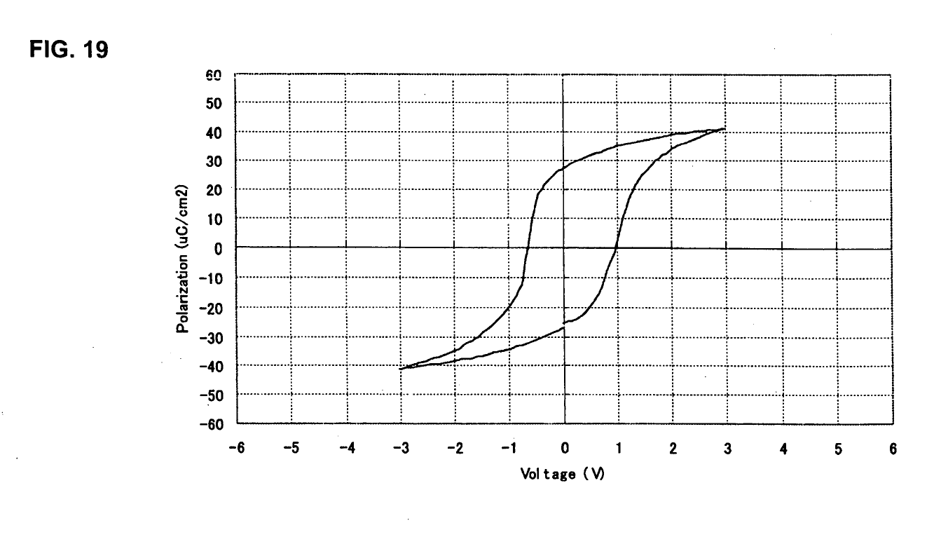

To compare the ferroelectric characteristics of the capacitors here, hysteresis loops were obtained with both of the samples. The results obtained with Sample 3 and Sample 1 are shown in FIG. 18 and FIG. 19, respectively.

It is clear from the figure that a hysteresis loop that was not different from the initial characteristic (FIG. 11) at all was obtained with Sample 3. In other words, it was found that no characteristic deterioration was generated in the PZT thin film capacitor 107 at all even though it underwent the process of forming the wiring 111.

In Sample 3, because the AlOₓ thin film 110 is arranged under the wiring 111, it is believed that hydrogen generated in the process of forming the wiring 111 did not infiltrate in the TEOS-SiO₂ thin film 109 through its surface. Therefore, hydrogen that reaches the PZT thin film capacitor 107 hardly exists, and the characteristic deterioration from the initial state was completely prevented. It was confirmed that the provision of the AlOₓ thin film 110 on the inner wall of the contact hole and on the TEOS-SiO₂ thin film 109 (under of the wiring 111) was extremely effective in completely intercepting the PZT thin film capacitor 107 from the hydrogen atmosphere.

### EMBODIMENT EXAMPLE 3

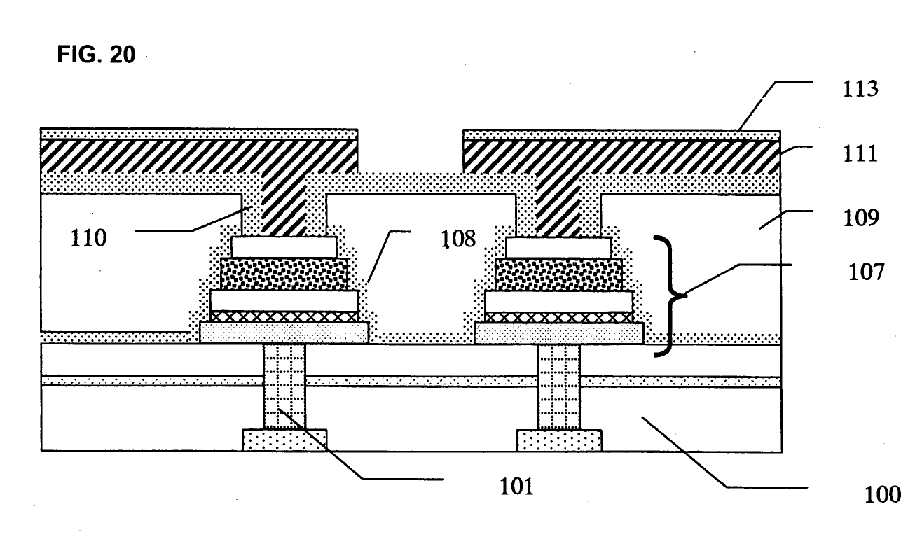

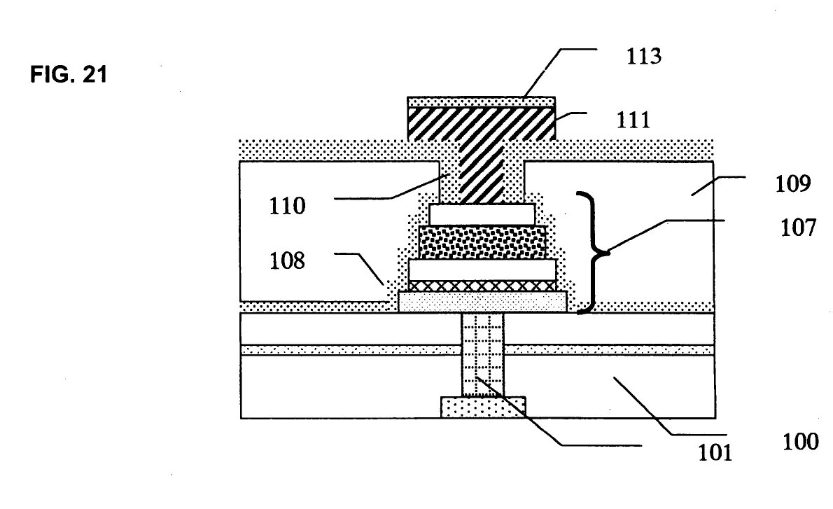

In Embodiment Example 1 and Embodiment Example 2, platinum is used as the wiring 111. A thin film that has a hydrogen barrier function can be disposed on the platinum surface. More specifically, by disposing an AlOx thin film, it becomes possible to prevent hydrogen that may be generated by a later process after the formation of the wiring 111 from infiltrating in the wiring 111. Though a sputter method is generally used for forming a film of platinum, an AlOx film is also continuously formed at the same time. More specifically, by stacking and then patterning platinum and AlOₓ films, the AlOₓ film can be stacked on and aligned with the platinum wiring, as shown in FIG. 20. FIG. 21 shows a cross section orthogonal to the cross section of the device shown in FIG. 20.

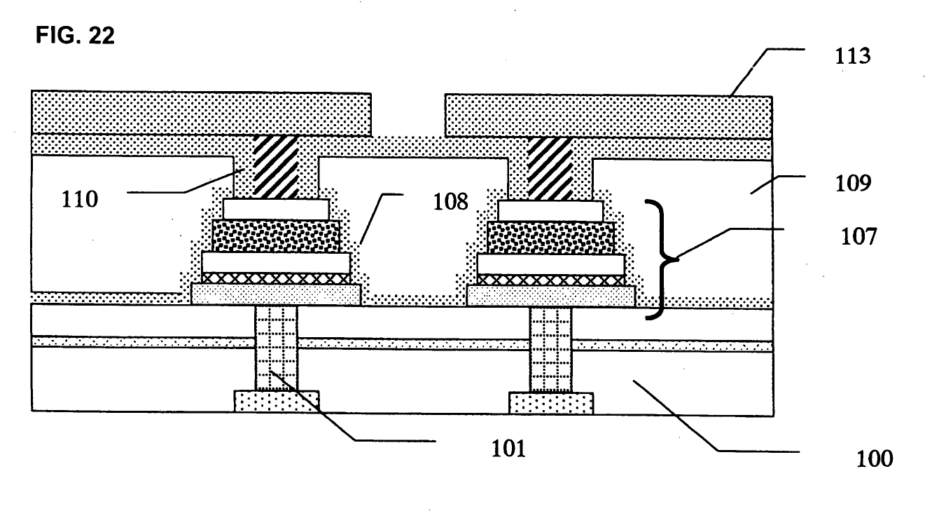

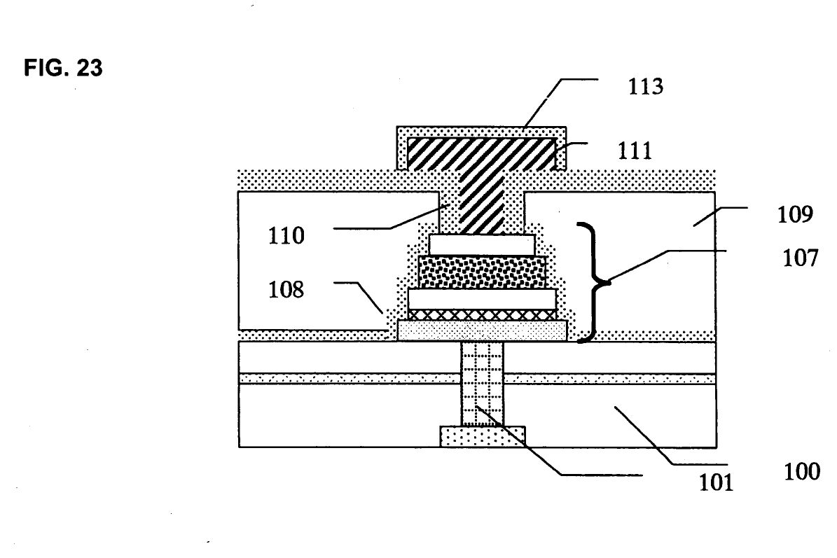

Also, after forming the wiring 111, it is also possible to form an AlOₓ thin film as a thin film having the hydrogen barrier function. More specifically, after a wiring material such as platinum is deposited and then patterned to form a wiring, an AlOₓ thin film is formed thereon, which gives a cross section shown in FIG. 22. A cross section orthogonal to this cross section is shown in FIG. 23.

It is also possible to arrange a material that has the hydrogen barrier function in the lowermost layer of the wiring 111. An oxide of iridium is enumerated as a candidate material. The layers can be stacked by initially laying an oxide of iridium in the stage of depositing the wiring material. As a result, even if hydrogen generated by a later process to be conducted after forming the wiring 111 infiltrates in the wiring 111, the hydrogen can be prevented from reaching the PZT thin film capacitor 107 through the contact hole.

### EMBODIMENT EXAMPLE 4

In the device formation process shown in Embodiment Example 1 and Embodiment Example 2, an underlying hydrogen barrier film 115 was formed, before an aperture of the contact hole of the semiconductor substrate 100 was formed. As its material, an AlOₓ thin film or the like enumerated in Embodiment Example 1 through Embodiment Example 3 can be used. In addition, any material can be used as long as the material has the hydrogen barrier function and insulation property. For example, an oxide of titanium, hafnium, zirconium, magnesium or tantalum can be used. Alternatively, a compound oxide containing plural kinds of these metals can also be used. For example, oxides such as Al₂MgO₄ and Al₂TiO₅ can be enumerated.

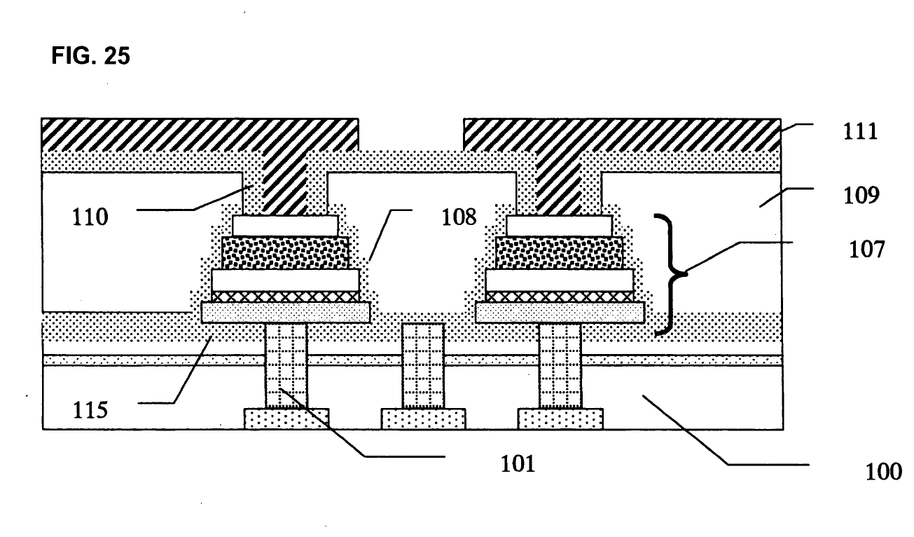

After the deposition of tungsten after openings of the contact holes were made, the sample was manufactured according to the procedure similar to the method described in Embodiment Example 2 (Sample 4). The device structure of this sample is shown in FIG. 25. The difference from Sample 3 indicated in Embodiment Example 2 (FIG. 17) is that the underlying hydrogen barrier film 115 is disposed.

To investigate differences that the structural difference between them gives to the process resistance of the capacitor, they were forcefully exposed to a hydrogen atmosphere. In the present embodiment example, they were heated for 30 minutes at 450° C. in a nitrogen atmosphere which contains hydrogen by 3% under the normal pressure. Characteristics of the PZT thin film capacitors after they had been processed were compared.

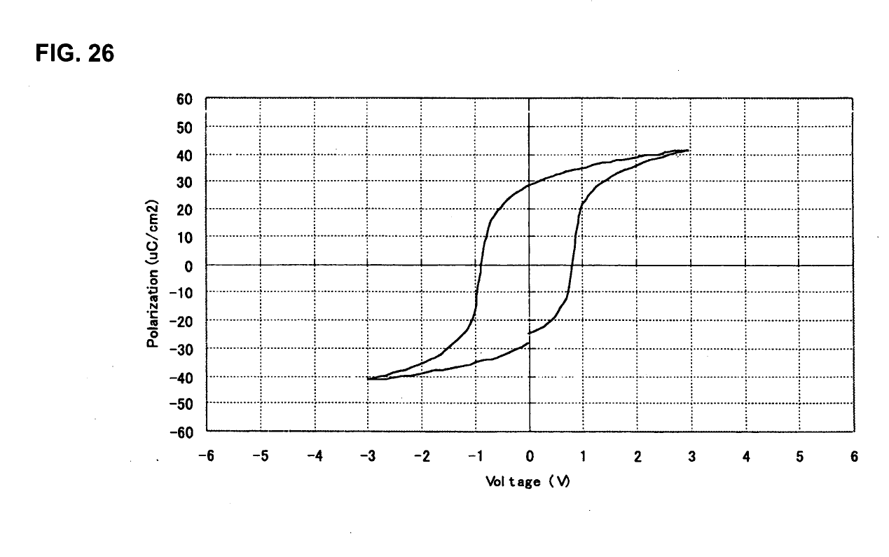

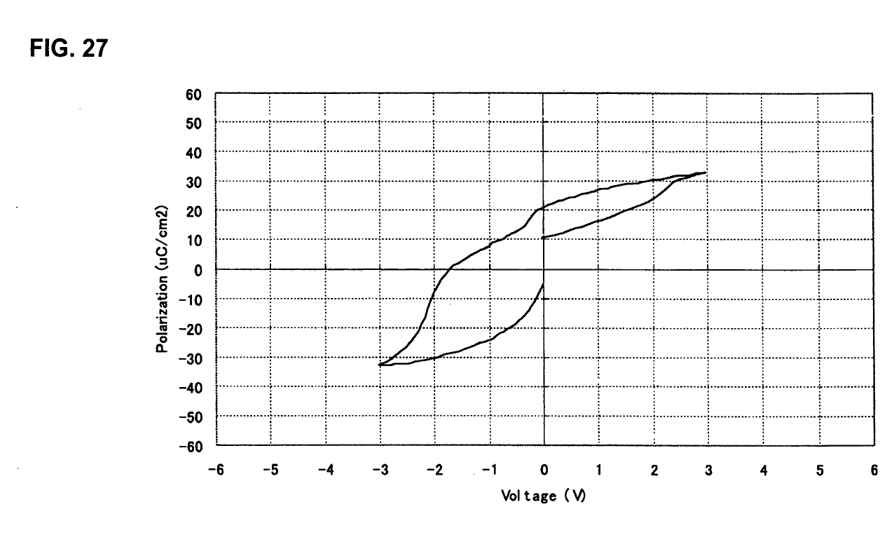

FIG. 26 and FIG. 27 show hysteresis loops obtained with Sample 3 and Sample 4, respectively. It is clear from the figures that there is hardly deterioration in the ferroelectric characteristic in Sample 4 compared with the PZT capacitor immediately after the formation. On the other hand, it is observed that the hysteresis loop becomes thin in Sample 3, which indicated that a drastic characteristic deterioration occurred. It became clear that a substantial characteristic difference appeared after processing with hydrogen because of the difference in the device structure between the two samples. That is, it is believed that the degree of process deterioration became substantially different depending on the absence or presence of the underlayer hydrogen barrier film 115.

Hydrogen diffuses in the TEOS-SiO₂ thin film 109 from its surface, and a certain amount reaches around the contact hole. However, in both of Sample 3 and Sample 4, because the sidewall of the PZT thin film capacitor 107 as well as the inner wall of the contact hole is covered with the AlOₓ thin film, hydrogen cannot infiltrate in the contact hole. For this reason, hydrogen would not reach the PZT thin film capacitor through the contact hole.

However, while the underlayer hydrogen barrier film 115 can function as a diffusion barrier against hydrogen infiltrating from the back surface of the substrate in Sample 4, in other words, the lower side of the PZT thin film capacitor, Sample 3 is defenseless. Therefore, it is believed that the substantial characteristic deterioration was caused by hydrogen infiltrating from the lower side of the PZT thin film capacitor in Sample 3.

Against hydrogen diffusion at a higher density or a higher temperature, it was found that it is extremely important to dispose a hydrogen barrier not only on the contact hole section in the upper part of the PZT thin film capacitor but also the lower electrode side at the same time.

### EMBODIMENT EXAMPLE 5

A PZT thin film capacitor 107 (FIG. 4) was manufactured by the method similar to Embodiment Example 1. Furthermore, a TEOS-SiO₂ film was deposited as an interlayer insulation film, and a contact hole was opened in an upper electrode of the PZT thin film capacitor (FIG. 6).

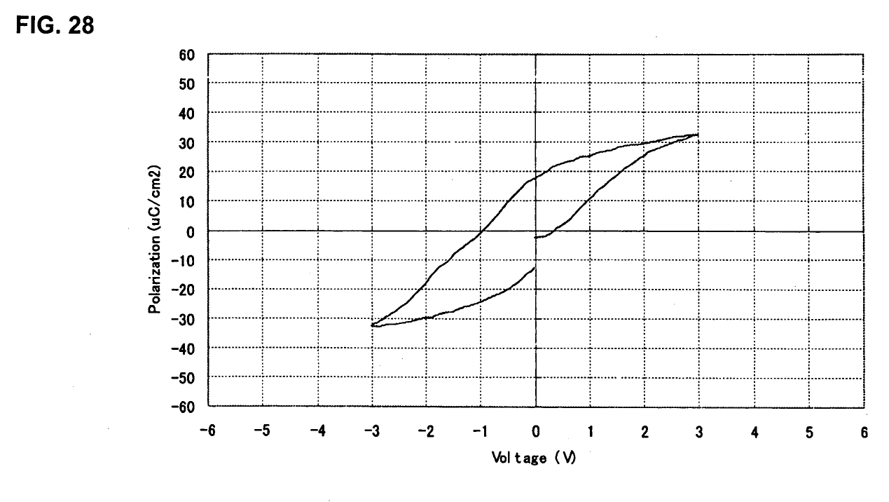

Next, an AlOₓ film was formed inside the contact hole and on the above-described TEOS-SiO₂ film by an ALCVD method (FIG. 7). Trimethylaluminum (TMA) was used as aluminum raw material in the present Embodiment Example and Embodiment Example 1. The aluminum raw material is not limited to TMA, but may be other organic aluminum materials. Water (H₂O) or ozone (O₃) can be used as an oxidant. In Embodiment Example 1, ozone was used as an oxidant. On the other hand, water was used as an oxidant in the present Embodiment Example for comparison. Though there is no difference as long as both of them worked as an oxidant against TMA, a large difference appeared in the capacitor characteristics depending on the difference of oxidant. FIG. 28 is a hysteresis loop obtained immediately after an AlOₓ was formed by using water for the oxidation of TMA in the present Embodiment Example. It is observed that there is a substantial deterioration compared with the characteristic of Sample 1 (FIG. 12) of Embodiment Example 1. Although it was formed in expectation to function as a barrier against hydrogen that would be generated in a process to be conducted later, it became clear that the capacitor was already damaged when the AlOₓ was formed.

When water molecules are supplied with TMA adsorbed to the surface of the substrate, methyl groups (CH₃) that bonds with aluminum atoms react with the water molecules such that ligands are exchanged, and change into OH groups. After all the methyl groups on the surface react and become saturated, unreacted water molecules become surplus molecules which are left in the film, and diffused to the PZT capacitor side. It is known that, when H₂O infiltrates ferroelectric (PZT), it damages the dielectric characteristics and ferroelectric characteristic. Therefore, because water molecules more than the amount necessary for oxidizing TMA is supplied in the AlOₓ film forming process in the present Embodiment Example, it is believed that the characteristic deterioration of the PZT capacitor is caused due to the water molecules taken into the PZT.

On the other hand, the following reaction takes place when ozone is used to oxidize TMA as in the case of Embodiment Example 1. First, when ozone is supplied with TMA adsorbed to the substrate, methyl groups that bond with aluminum atoms are resolved to carbon dioxide (CO₂) and water (H₂O) by a complete burning reaction. Water molecules among these by-products react with unreacted methyl groups, and generate OH groups in a similar manner as described above. Although water molecules are generated during the reaction, they are consumed in the TMA's ligands exchange reaction, such that their remaining amount in the AlOₓ film becomes extremely small. Accordingly, it is believed that the characteristic deterioration of the PZT capacitor occurred in this embodiment example was not caused. It became clear that the use of ozone as an oxidant of TMA was extremely effective in sustaining the characteristic of the PZT capacitor.

1. A ferroelectric memory element comprising:
a ferroelectric capacitor composed of a lower electrode, an oxide ferroelectric thin film and an upper electrode which are formed on a semiconductor substrate;
an interlayer insulation film formed on the ferroelectric capacitor;
a contact hole opened in the interlayer insulation film above the upper electrode; and
a wiring layer connected to the upper electrode through the contact hole,
wherein a thin film having a hydrogen barrier function is disposed on an inner wall of the contact hole.

2. A ferroelectric memory element according to claim 1, wherein a thin film having a hydrogen barrier function is formed on the interlayer dielectric film.

3. A ferroelectric memory element according to claim 1, wherein a surface of the wiring layer is covered with a thin film having a hydrogen barrier function.

4. A ferroelectric memory element according to claim 1, wherein a side surface of the wiring layer is covered with a thin film having a hydrogen barrier function.

5. A ferroelectric memory element according to claim 1, wherein the wiring layer comprises a precious metal.

6. A ferroelectric memory element according to claim 5, wherein an oxide of iridium is disposed at a lower most layer of the wiring layer.

7. A ferroelectric memory element according to claim 1, wherein a side surface of the ferroelectric capacitor is covered with a thin film having a hydrogen barrier function.

8. A ferroelectric memory element according to claim 1, wherein a thin film having a hydrogen barrier function is disposed below the ferroelectric capacitor.

9. A ferroelectric memory element according to claim 1, wherein the thin film having a hydrogen barrier function is an oxide including one or more elements selected from aluminum, titanium, hafnium, zirconium, magnesium and tantalum.

10. A ferroelectric memory element according to claim 1, wherein a region of the interlayer insulation film which contacts the ferroelectric capacitor is an O₃-TEOS SiO₂ film.

11. A method for manufacturing a ferroelectric memory element, comprising the steps of
a) stacking a lower electrode, an oxide ferroelectric thin film and an upper electrode in layers on a semiconductor substrate, and then patterning the layers to form a ferroelectric capacitor;
b) depositing an interlayer insulation film on the ferroelectric capacitor;
c) opening a contact hole in the interlayer insulation film above the upper electrode; and
d) coating a thin film having a hydrogen barrier function on the interlayer insulation film and inside the contact hole;
e) etching back the thin film having a hydrogen barrier function to remove the thin film having a hydrogen barrier function covering a bottom section of the contact hole;
f) depositing a conductive material in the contact hole to form a wiring layer that connects to the upper electrode.

12. A method for manufacturing a ferroelectric memory element according to claim 11, wherein, before the step e), an area other than an opening section of the contact hole is covered with a resist beforehand.

13. A method for manufacturing a ferroelectric memory element according to claim 11, wherein, in the step d), the thin film having a hydrogen barrier function is deposited by an Atomic-Layer deposition method.

14. A method for manufacturing a ferroelectric memory element according to claim 13, wherein the Atomic-Layer deposition method uses ozone as an oxidant to organic raw material.

15. A method for manufacturing a ferroelectric memory element according to claim 11, wherein, after the step c), the semiconductor substrate is heated in an oxygen atmosphere.

16. A method for manufacturing a ferroelectric memory element according to claim 15, wherein the heating is conducted below a crystallization temperature of the oxide ferroelectric thin film.

17. A method for manufacturing a ferroelectric memory element according to claim 11, wherein, in the step f), a thin film having a hydrogen barrier function is formed continuously on the conductive material.
